(19) United States
(12) Patent Application Publication
(10) Pub. No.: US 2007/0145509 A1
(43) Pub. Date: Jun. 28, 2007

(54) CMOS Image Sensor and Method for Manufacturing the Same

(76) Inventor: Keun Hyuk Lim, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/612,689

(22) Filed: Dec. 19, 2006

(30) Foreign Application Priority Data
Dec. 28, 2005 (KR) 10-2005-0132683

(51) Int. Cl. H01L 31/06

(52) U.S. Cl. 257/462

(57) ABSTRACT

A CMOS image sensor and a fabrication method thereof is provided. The CMOS image sensor includes a semiconductor substrate having an active area and an isolation area; a photodiode area and a transistor area formed on the active area; a gate electrode formed on the transistor area where the gate electrode has a first region having a first height and a second region having a second height, and diffusion areas formed on the photodiode area and the transistor area by implanting dopants

### RELATED APPLICATION(S)

This application claims the benefit under 35 U.S.C. §119(e), of Korean Patent Application Number 10-2005-0132683 filed Dec. 28, 2005, which is incorporated herein by reference in its entirety.

### FIELD OF THE INVENTION

The present invention relates to a complementary metal oxide semiconductor (CMOS) image sensor and a method for manufacturing the same.

### BACKGROUD OF THE INVENTION

In general, an image sensor is a semiconductor device for converting optical images into electric signals, and is mainly classified as a charge coupled device (CCD) or a CMOS image sensor.

The CCD has a plurality of photodiodes (PDs), which are arranged in the form of a matrix in order to convert optical signals into electric signals. The CCD includes a plurality of vertical charge coupled devices (VCCDs) provided between photodiodes and vertically arranged in the matrix so as to transmit electrical charges m the vertical direction when the electrical charges are generated from each photodiode. The CCD also includes a plurality of horizontal charge coupled devices (HCCDs) for transmitting the electrical charges from the VCCDs in the horizontal direction and a sense amplifier for outputting electric signals by sensing the electrical charges being transmitted in the horizontal direction.

However, the CCD has various disadvantages, such as a complicated drive mode and high power consumption. Also, the CCD requires multi-step photo processes, so the manufacturing process for the CCD is complicated.

In addition, since it is difficult to integrate a controller, a signal processor, and an analog/digital converter (A/D) converter) onto a single chip of the CCD, the CCD is not suitable for compact-size products.

Accordingly, the CMOS image sensor is spotlighted as a next-generation image sensor capable of solving the problem of the CCD.

The CMOS image sensor is a device employing a switching mode to sequentially detect an output of each unit pixel by means of MOS transistors, in which the MOS transistors are formed on a semiconductor substrate corresponding to the unit pixels through a CMOS technology, using peripheral devices, such as a controller and a signal processor.

That is, the CMOS image sensor includes a photodiode and a MOS transistor in each unit pixel, and sequentially detects the electric signals of each unit pixel in a switching mode to realize images.

Since the CMOS image sensor makes use of the CMOS technology, the CMOS image sensor has advantages such as low power consumption and a simple manufacturing process with relatively fewer photo processing steps.

In addition, the CMOS image sensor allows a product to have a compact size, because the controller, the signal processor, and the A/D converter can be integrated onto a single chip of the CMOS image sensor.

Therefore, CMOS image sensors have been extensively used in various applications, such as digital still cameras and digital video cameras.

The CMOS image sensors are classified as 3T-type, 4T-type or 5T-type CMOS image sensors according to the number of transistors formed in a unit pixel. The 3T-type CMOS image sensor includes one photodiode and three transistors, and the 4T-type CMOS image sensor includes one photodiode and four transistors.

FIG. 1 is an equivalent circuit diagram illustrating a 4T-type CMOS image sensor according to the related art and FIG. 2 is a layout view showing the 4T-type CMOS image sensor according to the related art.

As shown in FIG. 1, a unit pixel 100 of the 4T-type CMOS image sensor includes a photodiode 10, which is an optoelectronic device, and four transistors.

Here, the four transistors include a transfer transistor 20, a reset transistor 30, a drive transistor 40, and a select transistor 50. In addition, a load transistor 60 is electrically connected to an output teal OUT of each unit pixel 100.

Reference characters FD, Tx, Rx, Dx, and Sx represent a floating diffusion area, a gate voltage of the transfer transistor 20, a gate voltage of a reset transistor 30, a gate voltage of a drive transistor 40, and a gate voltage of a select transistor 50, respectively.

As shown in FIG. 2, the unit pixel of the CMOS image sensor has an active area defined thereon and an isolation layer formed on a predetermined area of the unit pixel except for the active areas. The photodiode PD is formed on a wider region of the active area, and gate electrodes 23, 33, 43 and 53 of four transistors are formed overlapping the remaining regions of the active area.

That is, the first gate electrode 23 corresponds to the transfer transistor 20, the second gate electrode 33 corresponds to the reset transistor 30, the third gate electrode 43 corresponds to the drive transistor 40, and the fourth gate electrode 53 corresponds to the select transistor 50.

Dopants are implanted into the active area of each transistor except for lower potions of the gate electrodes 23, 33, 43 and 53, so that source/drain (S/D) areas of the transistors are formed.

FIGS. 3A to 3C are sectional views taken along line I-I′ of FIG. 2 to illustrate a procedure for fabricating a CMOS image sensor according to the related art.

Referring to in FIG. 3A, an epitaxial process is performed relative to a high-density P type semiconductor substrate 61, thereby forming a low-density P type epitaxial layer 62.

Then, after defining an active area and an isolation area on the semiconductor substrate 61, an isolation layer 63 is formed on the isolation area trough an STI (shallow trench isolation) process.

In addition, a gate insulating layer 64 and a conductive layer (for example, a high-density multi-crystalline silicon layer) are sequentially deposited on the entire surface of the epitaxial layer 62 formed with the isolation layer 63. Then, the conductive layer and the gate insulating layer 64 are selectively removed to form a gate electrode 65.

After that referring to FIG. 3B, a first photoresist film is coated on the entire surface of the semiconductor substrate 61 and patterned by an exposure and development process to expose blue, green and red photodiode areas.

Then, n type dopants are implanted onto the epitaxial layer 62 using the patterned first photoresist film as a mask to form a low-density n type diffusion area 67 that serves as blue, green and red photodiode areas.

Then, the first photoresist film is removed and an insulating layer is deposited on the entire surface of the semiconductor substrate 61. An etch-back process is then performed to form an insulating layer sidewall 68 at both sides of the gate electrode 65.

Net after coating a second photoresist film on the entire surface of the semiconductor substrate 61, an exposure and development process is performed relative to the second photoresist film to cover the photodiode area and to expose the source/drain area of each transistor.

Then, n type dopants are implanted onto the exposed source/drain area at high concentration using the patterned second photoresist film as a mask to form an n type diffusion area (floating diffusion area) 70.

Referring to FIG. 3C, the second photoresist film is removed and a third photoresist film is coated on the entire surface of the semiconductor substrate 61. Then, an exposure and development process is performed relative to the third photoresist film, so that the third photoresist film is patterned to expose each photodiode area. Then, p type dopants are implanted onto the photodiode area having the n type diffusion area 67 using the patterned third photoresist film as a mask, thereby forming a p type division area 72 on a surface of the semiconductor substrate. After that, the third photoresist film is removed and a heat-treatment process is performed to expand each impurity diffusion area.

In a related art process, the low-density diffusion area 67 is formed through an ion implantation process employing 100 keV to 150 keV energy and I-line light. However, if the ion implantation process is performed with the above energy of 100 keV to 150 keV, ions that pass trough the gate electrode of the transfer transistor may be implanted into the semiconductor substrate below the gate electrode, thereby unnecessarily forming a channeling area A.

The width of the channeling area changes depending on the energy and light used in the ion implantation process, and the threshold voltage of the transfer transistor changes depending on the width of the channeling area. Thus, such width variation of the channeling area may degrade uniformity of characteristics of the transfer transistor.

### BRIEF SUMMARY

An object of embodiments of the present invention is to provide a CMOS image sensor having uniform characteristics and a method for manufacturing the same.

According to one aspect of the present invention, there is provided a CMOS image sensor comprising: a semiconductor substrate having an active area and an isolation area; a photodiode area and a transistor area formed on the active area; a gate electrode formed on the transistor area and having first and second heights; and a diffusion area formed on the photodiode area and the transistor area by implanting dopants.

According to another aspect of the present invention, there is provided a method for fabricating a CMOS image sensor, the method comprising: forming an active area and an isolation area on a semiconductor substrate; forming a gate insulating layer and a gate electrode on the active area; partially etching the gate electrode such that the gate electrode has first and second heights; and forming a first diffusion area by implanting dopants onto a photodiode area of the active area, and forming a channeling area at a lower portion of the gate electrode having the fist height by implanting dopants into the gate electrode.

According to still another aspect of the present invention, there is provided a CMOS image sensor comprising: a semiconductor substrate having an active area and an isolation area; a photodiode area and a transistor area formed on the active area; a gate electrode formed on the transistor area; a first diffusion area formed on the photodiode area by implanting dopants; a second diffusion area formed on the transistor area by implanting dopants; and a channeling area formed at a predetermined lower portion of the gate electrode.

### BRIEF DESCRIPTON OF THE DRAWINGS

FIG. 1 is an equivalent circuit diagram illustrating a 4T-type CMOS image sensor according to the related art;

FIG. 2 is a layout view showing a unit pixel of a 4T-type CMOS image sensor according to the related art;

FIGS. 3A to 3C are sectional views taken along line I-I′ of FIG. 2 to illustrate a procedure for fabricating a CMOS image sensor according to the related art and

FIGS. 4A to 4E are sectional views taken along line I-I′ of FIG. 2 to illustrate a procedure for fabricating a CMOS image sensor according to an embodiment of the present invention.

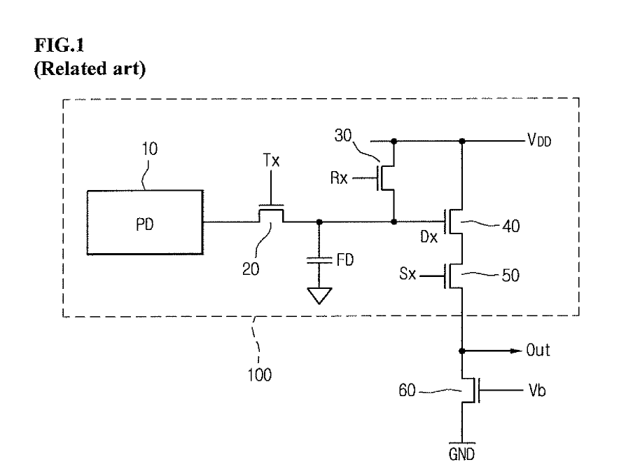

### DETAILED DESCRIPTON OF THE PREFERRED EMBODIMENTS

Hereinafter, preferred embodiments of the present invention will be described with reference to the accompanying drawings.

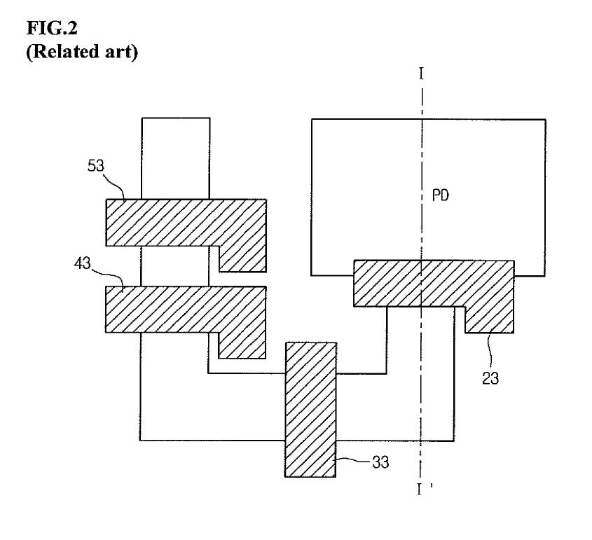

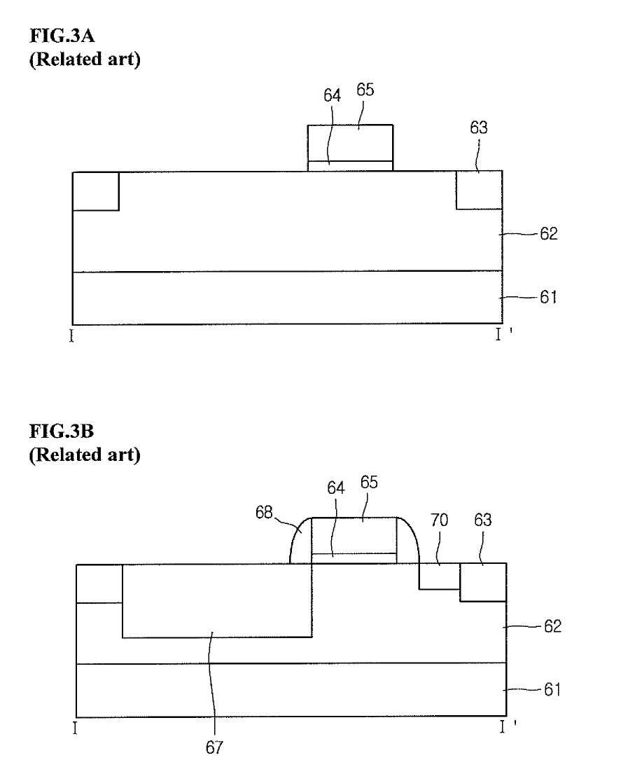

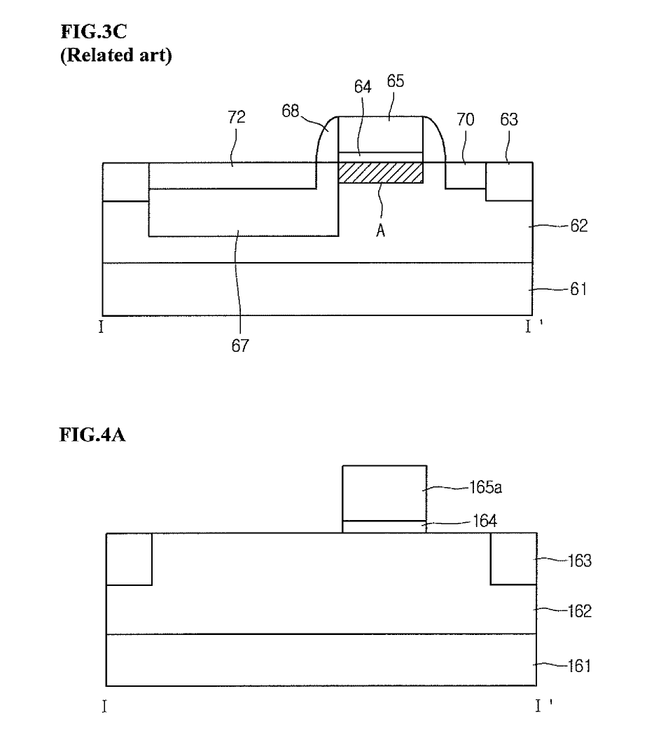

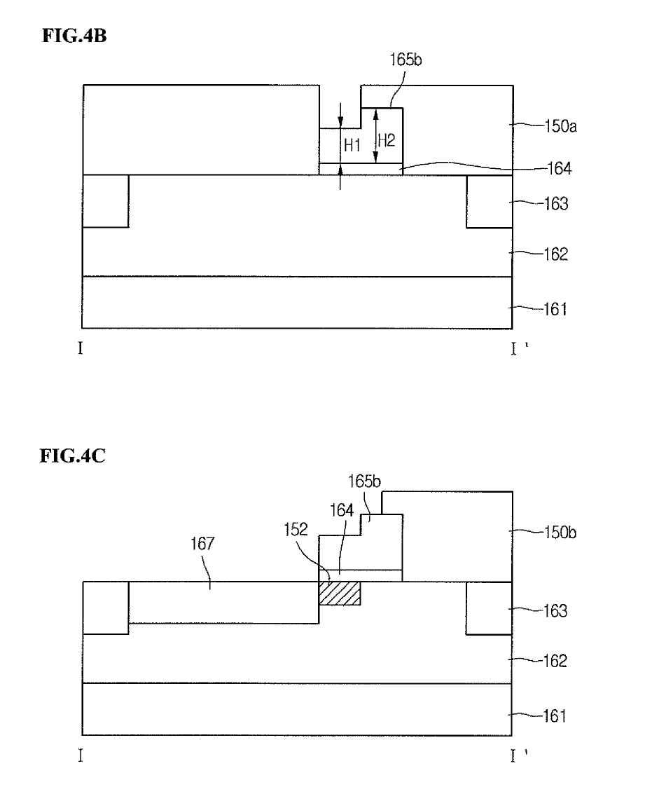

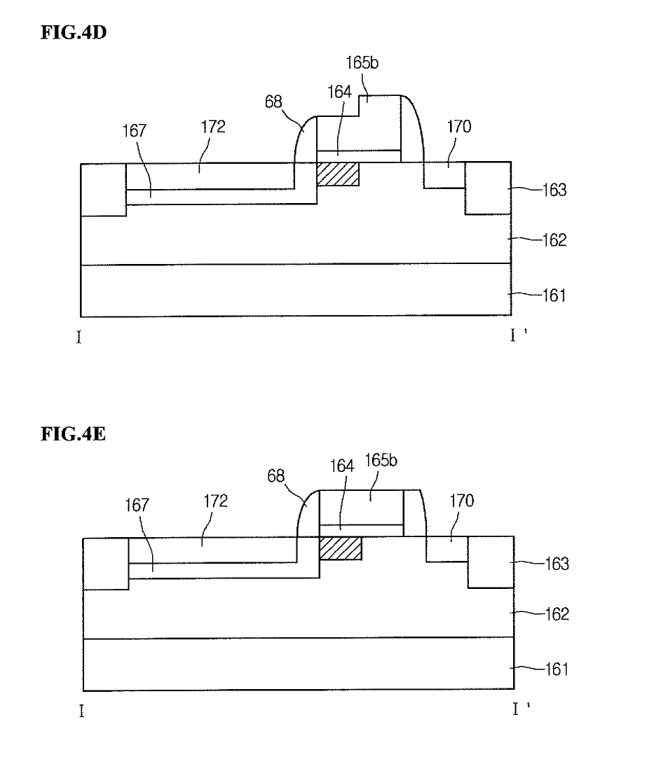

FIGS. 4A to 4E are sectional views taken along line I-I′ of FIG. 2 to illustrate a procedure for fabricating a CMOS image sensor according to an embodiment of the present invention.

Referring to FIG. 4A, an epitaxal process can be performed with respect to a high-density P type semiconductor substrate 161, thereby forming a low-density P type epitaxial layer 162.

Then, after defining an active area and an isolation area on the semiconductor substrate 161, an isolation layer 163 can be formed on the isolation area through an STI (shallow trench isolation) process.

Although not shown in the figures, the process for forming the isolation layer 163 can be as follows:

First, a pad oxide layer, a pad nitride layer and a TEOS (tetra ethyl ortho silicate) oxide layer are sequentially formed on a semiconductor substrate. Then, a photoresist film is formed on the TEOS oxide layer. After that, the photoresist film is subject to an exposure and development process using a mask that defines an active area and an isolation area, thereby patterning the photoresist film. At this time, the photoresist film formed on the isolation area is removed.

Then, the pad oxide layer, the pad nitride layer and the FOS oxide layer on the isolation area are selectively removed using the patterned photoresist film as a mask

Next the isolation area of the semiconductor substrate is etched to a predetermined depth using the patterned pad oxide layer, pad nitride layer and TEOS oxide layer as an etch mask, thereby forming a trench. After that the photoresist film is completely removed.

Then, the trench is filled with an insulating material, thereby forming the isolation layer 163 in the trench. After that the pad oxide layer, the pad nitride layer and the TEOS oxide layer are removed.

Referring back to FIG. 4A, a gate insulating layer 164 and a conductive layer (for example, a silicon layer) can be sequentially deposited on the entire surface of the epitaxial layer 162 formed with the isolation layer 163.

The gate insulating layer 164 can be formed through a thermal oxidation process or a CVD process.

Subsequently, the conductive layer and the gate insulating layer 164 can be selectively removed to form a gate electrode 165a.

In a specific embodiment the gate electrode 165 may have a thickness in a range of 3300 Å to 3700 Å.

Then, referring to FIG. 4B, a photoresist film can be coated on the entire surface of the semiconductor substrate including the gate electrode 165a, and selectively patterned by an exposure and development process to expose a predetermined area of the gate electrode 165a, thereby forming first photoresist film pattern 150a. Then, the exposed gate electrode is etched to a predetermined thickness using the first photoresist film pattern 150a as an etch mask, thereby forming a gate electrode 165b having a dual-height configuration including a first height H1 and a second height H2.

The first height H1 of the gate electrode 165b can be in a range of 1800 Å to 2000 Å, and the second height H2 of the gate electrode 165b can be in a range of 3300 Å to 3700 Å.

Then, referring to FIG. 4C, the first photoresist film pattern 150a is removed, and a second photoresist film can be coated on the entire surface of the semiconductor substrate formed with the gate electrode 165b. Then, the second photoresist film can be patterned using an exposure and development process to expose each photodiode area, thereby forming a second photoresist film pattern 150b. Second conductive type (n type) dopants can be implanted at low concentration onto the epitaxial layer 162 using the patterned second photoresist film 150b as a mask to form an n type diffusion area 167 in the photodiode area.

An energy of 100 keV to 150 keV and I-line light can be used in the ion implantation process to form the n type diffusion area 167. During the ion implantation process, a channeling area 152 is formed by ions that have passed through the gate electrode having the first height H1.

According to the related art the channeling area A changes depending on the process conditions of the ion implantation process, thereby causing variation of the threshold voltage of each transfer transistor. However, according to embodiments of the present invention, since the gate electrode has a first height H1, the channeling area 152 can be uniformly formed in each transfer transistor even if the process conditions of the ion implantation process are changed. Thus, it is possible to prevent the threshold voltage of the transfer transistor from being changed.

In addition, the energy level of the channeling area can be lowered, so the transfer characteristics of the transfer transistor can be improved.

Referring to FIG. 4D, the photoresist film pattern 150b can be removed, and an insulating layer can be deposited on the entire surface of the semiconductor substrate 161 including the diffusion area 167. An etch-back process can then be performed to form spacers 168 at both sides of the gate electrode 165b.

Next, after coating a third photoresist film on the entire surface of the semiconductor substrate 161 including the spacers 168, an exposure and development process is performed relative to the third photoresist film to cover the photodiode areas and to expose the source/drain area (or floating diffusion area) of each transistor.

Then, second conductive type (n type) dopants can be implanted at high concentration onto the exposed source/drain area using the patterned third photoresist film as a mask, thereby forming an n type diffusion area (floating diffusion area) 170.

After that, the third photoresist film is removed and a fourth photoresist film can be coated on the entire surface of the semiconductor substrate 161. Then, an exposure and development process can be performed relative to the fourth photoresist film, so that the fourth photoresist film is patterned to expose each photodiode area. Then, first conductive type (p type) dopants can be implanted onto the epitaxial layer 162 formed with the n type diffusion area 167 using the patterned fourth photoresist film as a mask to form a p type diffusion area 172 on the surface of the epitaxial layer 162.

After that the fourth photoresist film is removed and a heat-treatment process can be performed to diffuse each impurity diffusion area.

Referring to FIG. 4E, in a further embodiment a process for removing a part of the gate electrode 165b can be added so as to uniformly set the height of the gate electrode 165b.

According to an embodiment of the present invention, since the gate electrode has a dual-height configuration, the channeling area can be uniformly formed in each transfer transistor when the ion implantation process is performed for forming a diffusion area. Thus, it is possible to prevent the threshold voltage of each transfer transistor from being changed and to improve uniformity in characteristics of each transfer transistor.

It should be understood that the examples and embodiments described herein are for illustrative purposes only and that various modifications or changes in light thereof will be suggested to persons skilled in the art and are to be included within the spirit and purview of this application.

I claim:

1. A CMOS image sensor comprising:
a semiconductor substrate having an active area and an isolation area, wherein the active area includes a photodiode area and a transistor area;
a gate electrode formed on the transistor areas wherein the gate electrode comprises a first region having a first height and a second region having a second height; a first diffusion area formed on the photodiode area; and
a second diffusion area formed on the transistor area.

2. The CMOS image sensor according to claim 1, wherein the first height is in a range of 1800 Å to 2000 Å, and the second height is in a range of 3300 Å to 3700 Å.

3. The CMOS image sensor according to claim 1, wherein a channeling area is formed below the first region of the gate electrode having the first height without being formed below the second region of the gate electrode having the second height.

4. The CMOS image sensor according to claim 1, wherein spacers are formed at both sides of the gate electrode.

5. The CMOS image sensor according to claim 1, wherein the first diffusion area comprises: a second conductive type diffusion region formed on the photodiode area and a first conductive type diffusion region formed on the second conductive type diffusion region.

6. The CMOS image sensor according to claim 1, wherein the second diffusion area comprises a second conductive type diffusion region formed on the transistor area.

7. A method for fabricating a CMOS image sensor, comprising:
defining an active area and an isolation area on a semiconductor substrate;
forming a gate insulating layer and a gate electrode on the active area;
partially etching the gate electrode such that the gate electrode has a first region having a fist height and a second region having a second height:
forming a first diffusion area in a photodiode area of the active area; and forming a channeling area in the semiconductor substrate below the
first region of the gate electrode having the first height.

8. The method according to claim 7, further comprising
forming spacers at sidewalls of the gate electrode;
forming a second diffusion area by implanting dopants onto the transistor area; and
forming a third diffusion area by implanting dopants onto the first diffusion area.

9. The method according to claim 7, wherein the first height is in a range of 1800 Å to 2000 Å, and the second height is in a range of 3300 Å to 3700 Å.

10. The method according to claim 7, further comprising planarizing the gate electrode after forming the channeling area.

11. The method according to claim 7, wherein forming a first diffusion area and forming a channeling area comprises: implanting dopants onto the photodiode area and the gate electrode using an implantation energy of 100 keV to 150 keV and I-line light.

12. A CMOS image sensor, comprising:
a photodiode area and a transistor area defined on an active area of a semiconductor substrate;
a gate electrode formed on the transistor area;
a first diffusion area formed on the photodiode area; a second diffusion area formed on the transistor area; and
a channeling area formed at a predetermined lower portion of the gate electrode.

13. The CMOS image sensor according to claim 12, further comprising spacers formed at both sides of the gate electrode.

14. The CMOS image sensor according to claim 13, wherein the spacers formed at both sides of the gate electrode have shapes different from each other.

15. The CMOS image sensor according to claim 12, wherein the first diffusion area comprises a second conductive type diffusion region formed on the photodiode area, and a first conductive type diffusion region formed on the second conductive type diffusion region.

16. The CMOS image sensor according to claim 12, wherein the second diffusion area comprises a second conductive type diffusion region formed on the transistor area.
